(19) United States
(12) Patent Application Publication
(10) Pub. No.: US 2025/0393338 A1
(43) Pub. Date: Dec. 25, 2025

(54) LIGHT RECEIVING DEVICE

(71) Applicant: SUMITOMO ELECTRIC INDUSTRIES, LTD., Osaka (JP)

(72) Inventors: Ryo SUGAHARA, Osaka-shi (JP); Kazutoshi NATSUME, Osaka-shi (JP)

(73) Assignee: SUMITOMO ELECTRIC INDUSTRIES, LTD., Osaka (JP)

(21) Appl. No.: 19/227,247

(22) Filed: Jun. 3, 2025

(30) Foreign Application Priority Data
Jun. 25, 2024 (JP) 2024-101991

(51) Int. Cl. H10F 77/124; H10F 30/223

(52) U.S. Cl. CPC H10F 77/1248; H10F 30/223

(57) ABSTRACT

A light receiving device includes a first semiconductor layer, a light-absorbing layer, a second semiconductor layer, and a third semiconductor layer that are stacked in this order, a first electrode electrically connected to the first semiconductor layer, and a second electrode electrically connected to the third semiconductor layer. The third semiconductor layer is configured to form a first mesa protruding from the second semiconductor layer. The first semiconductor layer has a first conductivity type. The second semiconductor layer and the third semiconductor layer have a second conductivity type. An impurity concentration in the third semiconductor layer is higher than an impurity concentration in the second semiconductor layer. In the second semiconductor layer, an impurity concentration of a portion close to the light-absorbing layer is lower than an impurity concentration of a portion close to the third semiconductor layer.

### CROSS REFERENCE TO RELATED APPLICATIONS

This application claims priority based on Japanese Patent Application No. 2024-101991 filed on Jun. 25, 2024, and the entire contents of the Japanese patent application are incorporated herein by reference.

### TECHNICAL FIELD

The present disclosure relates to a light receiving device.

### BACKGROUND

In a light receiving device, an n-type semiconductor layer, an undoped light-absorbing layer, and a p-type semiconductor layer are stacked to form a positive-intrinsic-negative (pin) junction (see, for example, patent literature 1: WO 2008/090733).

### SUMMARY

A light receiving device according to the present disclosure includes a first semiconductor layer, a light-absorbing layer, a second semiconductor layer, and a third semiconductor layer that are stacked in this order, a first electrode electrically connected to the first semiconductor layer, and a second electrode electrically connected to the third semiconductor layer. The third semiconductor layer is configured to form a first mesa protruding from the second semiconductor layer. The first semiconductor layer has a first conductivity type. The second semiconductor layer and the third semiconductor layer have a second conductivity type. An impurity concentration in the third semiconductor layer is higher than an impurity concentration in the second semiconductor layer. In the second semiconductor layer, an impurity concentration of a portion close to the light-absorbing layer is lower than an impurity concentration of a portion close to the third semiconductor layer.

### BRIEF DESCRIPTION OF THE DRAWINGS

FIG. 1 is a plan view illustrating a light receiving device according to an embodiment.

FIG. 2A is a cross-sectional view illustrating the light receiving device.

FIG. 2B is a cross-sectional view illustrating the light receiving device.

FIG. 3 is a cross-sectional view illustrating a light receiving device according to a comparative example.

FIG. 4A is a schematic diagram illustrating an impurity concentration.

FIG. 4B is a schematic diagram illustrating energy levels.

FIG. 5A is a schematic diagram illustrating an impurity concentration.

FIG. 5B is a schematic diagram illustrating an energy levels.

FIG. 6A is a cross-sectional view illustrating a light receiving device according to a second embodiment.

FIG. 6B is a schematic diagram illustrating an impurity concentration.

FIG. 7A is a cross-sectional view illustrating a light receiving device according to a third embodiment.

FIG. 7B is a schematic diagram illustrating an impurity concentration.

FIG. 8A is a cross-sectional view illustrating a light receiving device according to a fourth embodiment.

FIG. 8B is a schematic diagram illustrating an impurity concentration.

### DETAILED DESCRIPTION

Since layers having different impurity concentrations are contact with each other, carriers are diffused between semiconductor layers due to the concentration difference. The highly doped contact layer may be mesa-shaped. The junction interface of the semiconductor layers having different concentration differences is revealed on the side surfaces of the mesa. Since the concentration difference between the bonded semiconductor layers is large, the dark current increases at the side surfaces of the mesa due to carrier diffusion. Further, the built-in potential increases in accordance with the diffusion of carriers, and the electric field concentrates on the junction interface. Edge breakdown is likely to occur. Thus, an object of the present disclosure is to provide a light receiving device capable of reducing dark current and alleviating electric field concentration.

### DESCRIPTION OF EMBODIMENTS OF PRESENT DISCLOSURE

First, the contents of embodiments of the present disclosure will be listed and explained.
(1) Alight receiving device according to an aspect of the present disclosure includes a first semiconductor layer, a light-absorbing layer, a second semiconductor layer, and a third semiconductor layer that are stacked in this order, a first electrode electrically connected to the first semiconductor layer, and a second electrode electrically connected to the third semiconductor layer. The third semiconductor layer is configured to form a first mesa protruding from the second semiconductor layer. The first semiconductor layer has a first conductivity type. The second semiconductor layer and the third semiconductor layer have a second conductivity type. An impurity concentration in the third semiconductor layer is higher than an impurity concentration in the second semiconductor layer. In the second semiconductor layer, an impurity concentration of a portion close to the light-absorbing layer is lower than an impurity concentration of a portion close to the third semiconductor layer. The difference in the impurity concentration between the second semiconductor layer and the second semiconductor layer is reduced. Diffusion of carriers between layers is alleviated. The dark current can be reduced at the junction interface revealed on the side surfaces of the first mesa. Built-in potential associated with carrier diffusion is reduced. It is possible to alleviate the electric field concentration at the junction interface.
(2) In the above (1), the second semiconductor layer may include a plurality of semiconductor layers stacked between the light-absorbing layer and the third semiconductor layer. An impurity concentration in a semiconductor layer of the plurality of semiconductor layers close to the third semiconductor layer may be higher than an impurity concentration in a semiconductor layer of the plurality of semiconductor layers close to the light-absorbing layer. The concentration difference in impurity between the second semiconductor layer and the second semiconductor layer is reduced. The dark current can be reduced. The electric field concentration can be alleviated.
(3) In the above (1) or (2), the second semiconductor layer may include a fourth semiconductor layer, a fifth semiconductor layer, and a sixth semiconductor layer. The light-absorbing layer, the fourth semiconductor layer, the fifth semiconductor layer, the sixth semiconductor layer, and the third semiconductor layer may be stacked in this order. An impurity concentration in the fifth semiconductor layer may be higher than an impurity concentration in the fourth semiconductor layer. An impurity concentration in the sixth semiconductor layer may be higher than an impurity concentration in the fifth semiconductor layer. The impurity concentration is reduced between the second semiconductor layer and the sixth semiconductor layer. The impurity concentration is also reduced between the sixth semiconductor layer and the fourth semiconductor layer. The dark current can be reduced. The electric field concentration can be alleviated.
(4) In the above (2) or (3), the plurality of semiconductor layers included in the second semiconductor layer may be formed of a same material. Crystal lattice strain is less likely to occur.
(5) In any one of the above (1) to (4), the second semiconductor layer may be formed of a material different from a material of the third semiconductor layer. The second semiconductor layer and the third semiconductor layer form a heterojunction. The dark current can be reduced at the heterojunction interface, and the electric field concentration can be alleviated.
(6) In any one of the above (1) to (5), the first mesa formed by the second semiconductor layer may have a ring shape in a planar shape. In a ring shape junction interface, the dark current can be reduced and the electric field concentration can be alleviated.
(7) In any one of the above (1) to (6), the light-absorbing layer and the second semiconductor layer may be configured to form a second mesa. A depletion region is expanded in the second mesa. The capacitance is reduced by the depletion of the third semiconductor layer.
(8) In any one of the above (1) to (7), the first semiconductor layer may have an n-type conductivity type. The second semiconductor layer and the third semiconductor layer may have a p-type conductivity type. The impurity concentration between the p-type third semiconductor layer and the p-type second semiconductor layer is reduced, and the diffusion of carriers is alleviated.
(9) In any one of the above (1) to (8), the light receiving device may be an avalanche photodiode. The light receiving device may include a multiplication layer stacked between the first semiconductor layer and the third semiconductor layer. It is possible to alleviate electric field concentration at the junction interface between the second semiconductor layer and the third semiconductor layer, thus reducing edge breakdown.

### Details of Embodiments of Present Disclosure

Specific examples of the light receiving device according to the embodiments of the present disclosure will be described below with reference to the drawings. The present disclosure is not limited to these examples, but is defined by the scope of the claims, and is intended to include all modifications within the meaning and scope equivalent to the scope of the claims.

### First Embodiment

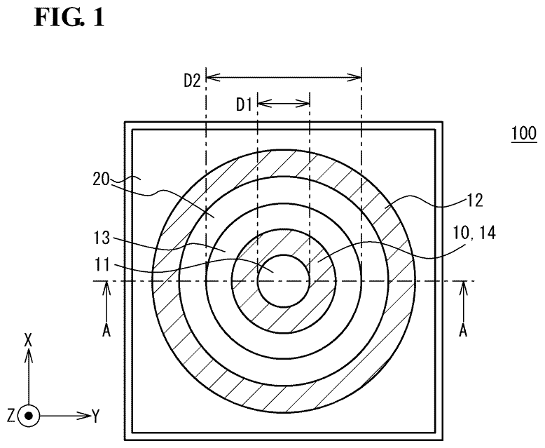

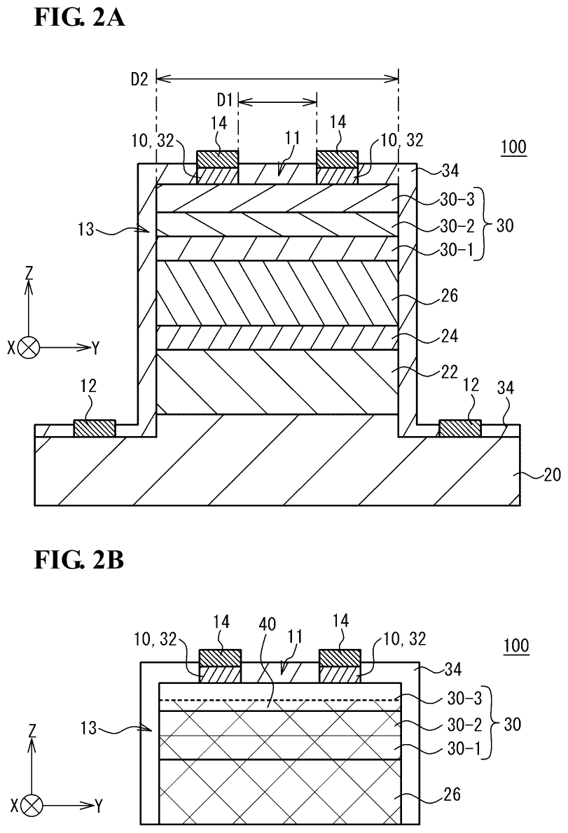

FIG. 1 is a plan view illustrating a light receiving device 100 according to an embodiment. FIG. 2A is a cross-sectional view illustrating the light receiving device 100, and showing a cross-section which is taken along line A-A of FIG. 1. The light receiving device 100 is an avalanche photodiode (APD) and is used for, for example, light detection and ranging (LiDAR).

As shown in FIG. 1, the light receiving device 100 has a mesa 10 (first mesa), a mesa 13 (second mesa), an electrode 12 (first electrode), an electrode 14 (second electrode), and a buffer layer 20 (first semiconductor layer). The upper surface of the buffer layer 20 is parallel to an XY plane. Two sides of the buffer layer 20 are parallel to an X-axis. The other two sides are parallel to a Y-axis. A Z-axis is a thickness direction of the buffer layer 20. The X-axis, the Y-axis, and the Z-axis are orthogonal to each other. In FIG. 1, diagonal lines are indicated on the electrode 12 and the electrode 14.

In a plan view, the mesa 10, the electrode 12, and the electrode 14 have a circular ring shape (ring shape). The mesa 13 is circular. In the XY plane, the mesa 10 is located inside the mesa 13. The electrode 14 is provided on the mesa 10. A portion inside the electrode 14 functions as a light receiving region 11. A diameter D1 of the light receiving region 11 (inner diameter of the mesa 10) is, for example, 200 μm. A diameter D2 of the mesa 13 is larger than the inner diameter D1 of the mesa 10, and is, for example, 300 μm. The electrode 12 is provided outside the mesa 10 and the mesa 13, and surrounds the mesa 13.

As shown in FIG. 2A, the light receiving device 100 has the buffer layer 20, a multiplication layer 22, an adjusting layer 24, a light-absorbing layer 26, a window layer 30 (second semiconductor layer), and a contact layer 32 (third semiconductor layer), and may include other semiconductor layers. A semiconductor substrate (not shown) may be provided under the buffer layer 20. The central portion of the buffer layer 20 in the XY plane protrudes in the Z-axis direction from the outer peripheral portion of the buffer layer 20. The adjusting layer 24, the light-absorbing layer 26, and the window layer 30 are stacked in this order on the protruding portion of the buffer layer 20. The mesa 13 includes the buffer layer 20, the adjusting layer 24, the light-absorbing layer 26, and the window layer 30.

The window layer 30 includes three semiconductor layers: a semiconductor layer 30-1 (fourth semiconductor layer), a semiconductor layer 30-2 (fifth semiconductor layer), and a semiconductor layer 30-3 (sixth semiconductor layer). The semiconductor layer 30-1, the semiconductor layer 30-2, and the semiconductor layer 30-3 are stacked in this order between the light-absorbing layer 26 and the contact layer 32. The semiconductor layer 30-1 is in contact with the light-absorbing layer 26. The semiconductor layer 30-2 is in contact with the semiconductor layer 30-1. The semiconductor layer 30-3 is in contact with the contact layer 32 to form a heterojunction.

The contact layer 32 is provided on the upper surface of the semiconductor layer 30-3. The contact layer 32 has a circular ring shape and protrudes from the semiconductor layer 30-3 in the Z-axis direction to form the mesa 10. The side surfaces and the upper surface of the mesa 10 are the contact layer 32. The side surfaces of the mesa 13 are formed of the layers from the multiplication layer 22 to the semiconductor layer 30-3. The upper surface of the mesa 13 is formed of the semiconductor layer 30-3.

The upper surfaces of the buffer layer 20, the side surfaces and upper surface of the mesa 13, and the side surfaces of the mesa 10 are covered with an insulation film 34. The insulation film 34 is provided on the upper surface of the mesa 10. The insulation film 34 has an opening at a position spaced apart from the mesa 13. The electrode 12 is provided on the opening. The insulation film 34 has an opening on the mesa 10. The electrode 14 is provided on the opening. The electrode 14 has a circular ring shape similar to the contact layer 32. The insulation film 34 is a passivation film and is formed of an insulator such as silicon nitride (SiN). The electrode 12 and the electrode 14 are formed of metal.

The buffer layer 20 has, for example, an n-type (first conductivity type) and is formed of n⁺ type indium phosphorus ((n⁺)-InP). The buffer layer 20 has, for example, a thickness of 1600 nm. The buffer layer 20 is doped with impurities such as silicon (Si). The impurity concentration is, for example, 1.0×10¹⁸ cm⁻³. The multiplication layer 22 is formed of, for example, undoped indium aluminum arsenide (i-InₓAl₁₋ₓAs (x=0.52)). The multiplication layer 22 has, for example, a thickness of 500 nm. The adjusting layer 24 is formed of, for example, p-type (second conductivity type) indium aluminum arsenide (p-InₓAl₁₋ₓAs (x=0.52)). The adjusting layer 24 has, for example, a thickness of 100 nm. The adjusting layer 24 is doped with impurities such as zinc (Zn). The impurity concentration is, for example, 3.0×10¹⁷ cm⁻³.

The light-absorbing layer 26 is formed of, for example, undoped indium gallium arsenide (i-InₓGa₁₋ₓAs (x=0.53). The light-absorbing layer 26 has, for example, a thickness of 1000 nm. Although an undoped semiconductor layer such as the light-absorbing layer 26 is not intentionally doped with impurities, it may be unintentionally doped with impurities of 1×10¹⁵ cm⁻³ order.

The semiconductor layer 30-1, the semiconductor layer 30-2, and the semiconductor layer 30-3 of the window layer 30 are formed of, for example, p-type InₓAl₁₋ₓAs (x=0.52). These three layers are doped, for example, with zinc (Zn) or tellurium (Te). Each thickness of the three layers are, for example, 200 nm. The band gap of the window layer 30 is wider than the band gap of the light-absorbing layer 26. The relative dielectric constant of the window layer 30 is lower than the relative dielectric constant of the light-absorbing layer 26.

The semiconductor layer 30-1 is (p⁺)-type. The semiconductor layer 30-2 is p-type. The semiconductor layer 30-3 is (p⁺)-type. That is, the impurity concentration of the semiconductor layer 30-3 is higher than the impurity concentrations of the semiconductor layer 30-2 and the semiconductor layer 30-1, and is, for example, 1×10¹⁸ cm⁻³. The impurity concentration of the semiconductor layer 30-2 is higher than the impurity concentration of the semiconductor layer 30-1, and is, for example, 1×10¹⁷ cm⁻³. The impurity concentration of the semiconductor layer 30-1 is, for example, 1×10¹⁶ cm⁻³.

The contact layer 32 is formed of, for example, p⁺-InₓGa₁₋ₓAs (x=0.53). The contact layer 32 has, for example, a thickness of 200 nm. The concentration of Zn doped in the contact layer 32 is higher than the impurity concentration of the semiconductor layer 30-3, and is, for example, 1×10¹⁹ cm⁻³. The semiconductor layer of the light receiving device 100 may be formed of a compound semiconductor other than the above.

### (Method of Manufacturing)

For example, the buffer layer 20 is stacked on one surface of the semi-insulating semiconductor substrate by metal organic chemical vapor deposition (MOCVD). On the opposite surface of the buffer layer 20 from the substrate, the multiplication layer 22, the adjusting layer 24, the light-absorbing layer 26, the window layer 30, and the contact layer 32 are epitaxially grown in this order. Impurities are doped to the window layer 30 and the like. The impurity concentration is controlled by adjusting the supply amount of the impurities.

Etching is performed to form the contact layer 32 into the ring shape mesa 10. The mesa 13 is formed by etching a portion of the window layer 30, the light-absorbing layer 26, the adjusting layer 24, the multiplication layer 22, and the buffer layer 20. The etching may be either dry etching or wet etching. The insulation film 34 is formed by plasma enhanced chemical vapor deposition (plasma CVD). By etching, openings are formed in the portions of the insulation film 34 that cover the upper surface of the mesa 10 and the upper surface of the buffer layer 20. The electrode 12 and the electrode 14 are formed by vacuum deposition and lift-off. The light receiving device 100 is formed.

The light receiving device 100 is capable of detecting light such as infrared light, for example, light with a wavelength of 1.55 μm. The operating voltage is, for example, 70 V. When using the light receiving device 100, a positive voltage is applied to the electrode 12, and a negative voltage is applied to the electrode 14.

FIG. 2B is a cross-sectional view illustrating the light receiving device 100, showing the light receiving device 100 when a reverse bias voltage is applied. FIG. 2B shows the light-absorbing layer 26 to the contact layer 32. In response to the applied voltage, a depletion region 40 is generated in the mesa 13 and expanded, for example, partway through the semiconductor layer 30-3 in the Z-axis direction, but does not reach the junction interface between the semiconductor layer 30-3 and the contact layer 32. The element capacitance is reduced by the depletion of the window layer 30. The operating band of the light receiving device 100 can be widened.

Light incident from the light receiving region 11 is absorbed by the light-absorbing layer 26. The light-absorbing layer 26 generates carriers (electron-hole pairs) by absorbing light. Carriers are moved by the electric field applied to the depletion region 40 and are output as a photocurrent. The adjusting layer 24 functions as an electric field adjusting layer. A high electric field is applied to the multiplication layer 22. Electrons collide with atoms in the multiplication layer 22, and thus more carriers are generated. Thus, the sensitivity is improved.

### Comparative Example

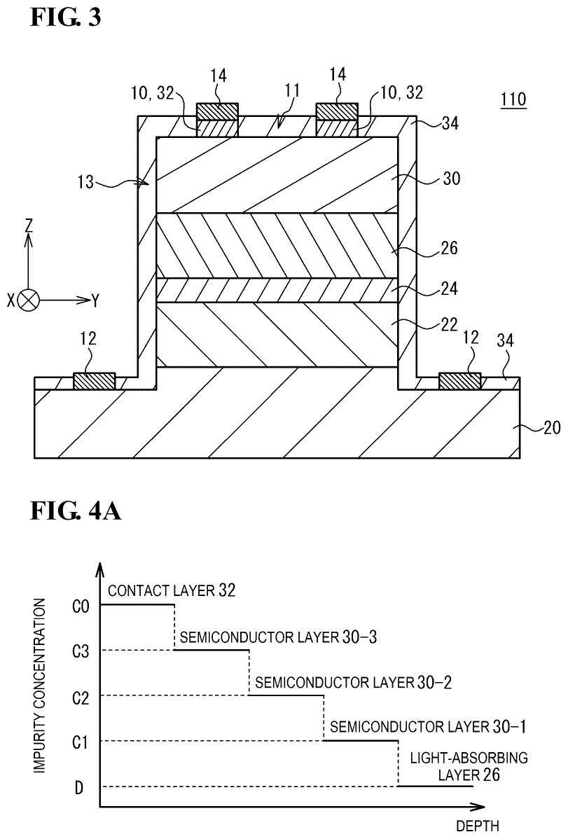

FIG. 3 is a cross-sectional view illustrating a light receiving device 110 according to a comparative example. One window layer 30 is provided between the light-absorbing layer 26 and the contact layer 32. The window layer 30 is formed of, for example, i-InAlAs. The impurity concentration is, for example, 1×10¹⁵ cm⁻³ or less. The window layer 30 has, for example, a thickness of 600 nm. Other configurations are the same as those of the light receiving device 100. Although not shown, in the comparative example, the depletion region is expanded to the junction interface between the window layer 30 and the contact layer 32.

### (Impurity Concentration)

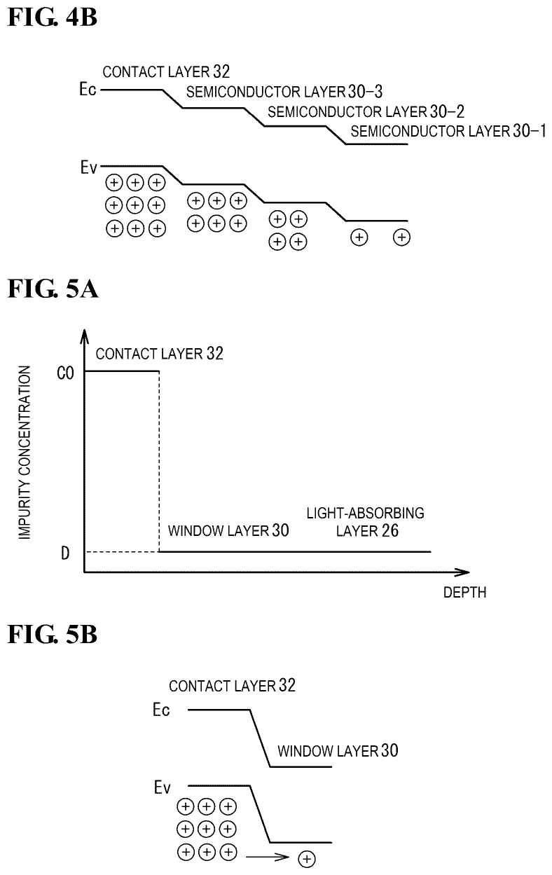

FIG. 4A and FIG. 5A are schematic diagrams illustrating impurity concentration. The horizontal axis represents the depth of the light receiving device in the Z-axis direction, and the contact layer 32 to the light-absorbing layer 26 are shown from left to right. The vertical axis represents the impurity concentration in the layer.

FIG. 4A shows the impurity concentration in the first embodiment. In FIG. 4A, the impurity concentrations of the semiconductor layer 30-1, the semiconductor layer 30-2, the semiconductor layer 30-3, and the contact layer 32 are referred to as C1, C2, C3, and C0, respectively. These concentrations are, for example, the values mentioned above. The impurity concentration of the light-absorbing layer 26 is referred to as D. An impurity concentration D is, for example, 1×10¹⁵ cm⁻³ order or lower.

Among the layers of FIG. 4A, the impurity concentration C0 of the contact layer 32 is the highest. The impurity concentration in the window layer 30 changes stepwise depending on the position, and becomes higher as it is closer to the contact layer 32, and becomes lower as it is farther from the contact layer 32. An impurity concentration C1 of the semiconductor layer 30-1 is higher than the impurity concentration of the light-absorbing layer 26. An impurity concentration C2 of the semiconductor layer 30-2 is higher than the impurity concentration C1 of the semiconductor layer 30-1, and is, for example, about 10 times the C1. An impurity concentration C3 of the semiconductor layer 30-3 is higher than the impurity concentration C2 of the semiconductor layer 30-2, and is, for example, about 10 times the C2. The impurity concentration C0 of the contact layer 32 is higher than the impurity concentration C3 of the semiconductor layer 30-3, and is, for example, about 10 times the C3.

FIG. 5A shows the impurity concentration in the comparative example. The window layer 30 and the light-absorbing layer 26 are undoped layers and have a similar level with the impurity concentrations D. The impurity concentration C0 of the contact layer 32 is higher than 10,000 or more times the impurity concentration D of the window layer 30 and the light-absorbing layer 26.

### (Carrier)

FIG. 4B and FIG. 5B are schematic diagrams illustrating energy levels. Ev represents the energy of valence band. Ec represents the energy of conduction band. The contact layer 32 and the window layer 30 are p-type and include holes as majority carriers. In FIG. 4B and FIG. 5B, holes are represented by + symbols. The number of + symbols does not accurately represent the concentration of carriers, however, layers with more symbols have a higher carrier concentration than those with fewer symbols.

FIG. 4B shows the energy levels in the first embodiment. From left to right in FIG. 4B, the contact layer 32 to the semiconductor layer 30-1 are shown. The carrier concentration of the contact layer 32 is higher than the carrier concentration of the semiconductor layer 30-3. The carrier concentration of the semiconductor layer 30-3 is higher than the carrier concentration of the semiconductor layer 30-2. The carrier concentration of the semiconductor layer 30-2 is higher than the carrier concentration of the semiconductor layer 30-1.

FIG. 5B shows the energy levels in the comparative example. The carrier density of the contact layer 32 is higher than that of the window layer 30. The carrier concentration difference between the contact layer 32 and the window layer 30 in FIG. 5B is larger than the carrier concentration difference between the adjacent layers in the example of FIG. 4B. Since the carrier concentration is largely changed, carriers are rapidly diffused from the contact layer 32 to the window layer 30. The dark current increases with the carrier diffusion. As shown in FIG. 3, in the comparative example, the contact layer 32 forming the mesa 10 are in contact with the window layer 30. The junction interface is revealed on the side surfaces of the mesa 10. Since there is a large carrier concentration difference at the revealed junction interface, the dark current increases.

As shown in FIG. 5B, the energy difference between the contact layer 32 and the window layer 30 is increased by the carrier diffusion, and the built-in potential is increased. Thus, a high electric field is generated near the junction interface. The depletion region expands to the i-type window layer 30 and reaches the junction interface with the contact layer 32. A high electric field is applied to the junction interface between the contact layer 32 and the window layer 30. Due to the concentration of the electric field, the edge breakdown is likely to occur at the interface.

As shown in FIG. 4B, according to the first embodiment, the carrier concentration difference between adjacent layers from the contact layer 32 to the semiconductor layer 30-1 is smaller compared to the comparative example. Diffusion of carriers between the layers is alleviated. Since the carrier diffusion is alleviated, the dark current is reduced and the built-in potential is reduced as compared with the comparative example.

According to the first embodiment, as shown in FIG. 2A, the light-absorbing layer 26, the window layer 30, and the contact layer 32 are stacked in this order. The contact layer 32 is a highly doped layer and forms the mesa 10. The window layer 30 includes the semiconductor layer 30-1, the semiconductor layer 30-2, and the semiconductor layer 30-3. The impurity concentrations of the three semiconductor layers of the window layer 30 are higher as they are closer to the contact layer 32 and lower as they are farther from the contact layer 32. That is, the impurity concentration of the semiconductor layer 30-3 is lower than the impurity concentration of the contact layer 32 and higher than the impurity concentration of the semiconductor layer 30-2. The impurity concentration of the semiconductor layer 30-2 is higher than the impurity concentration of the semiconductor layer 30-1. The concentration difference between the contact layer 32 and the semiconductor layer 30-3 is smaller than the concentration difference of impurities between the contact layer 32 and the window layer 30 in the comparative example. Diffusion of carriers is alleviated. The dark current can be reduced at the junction interface between the contact layer 32 revealed on the side surfaces of the mesa 10 and the semiconductor layer 30-3.

Since the concentration difference between the contact layer 32 and the semiconductor layer 30-3 is small, the built-in potential associated with carrier diffusion is also small. The electric field concentration at the junction interface between the contact layer 32 and the semiconductor layer 30-3 can be alleviated. It is possible to reduce the edge breakdown.

The concentration difference between adjacent layers in the contact layer 32 to the semiconductor layer 30-1 in the first embodiment is also smaller than the concentration difference between the contact layer 32 and the window layer 30 in the comparative example. The diffusion of carriers is also alleviated between the semiconductor layer 30-3 and the semiconductor layer 30-2 and between the semiconductor layer 30-2 and the semiconductor layer 30-1. The dark current can be reduced.

The impurity concentration of the contact layer 32 is, for example, about 10 times the impurity concentration of the semiconductor layer 30-3. The impurity concentration of the semiconductor layer 30-3 is, for example, about 10 times the impurity concentration of the semiconductor layer 30-2. The impurity concentration of the semiconductor layer 30-2 is, for example, about 10 times the impurity concentration of the semiconductor layer 30-1. The target value of the concentration in the manufacturing process may be set at different values for each layer in a 10-fold ratio as described above. The ratio of impurity concentration between adjacent layers may be 10 or less, for example, 8 or less, or 5 or less.

The buffer layer 20 has an n-type conductivity type. The window layer 30 and the contact layer 32 have a p-type conductivity type. The light-absorbing layer 26 is i-type. A pin junction is formed between the contact layer 32 and the buffer layer 20, and the light receiving device 100 functions as a photodiode. The impurity concentration between the p-type window layer 30 and the contact layer 32 is reduced, and the diffusion of carriers is alleviated. The contact layer 32 and the window layer 30 may be n-type. An n-type semiconductor layer may be provided opposite to the window layer 30 of the light-absorbing layer 26.

The semiconductor layer 30-1, the semiconductor layer 30-2, and the semiconductor layer 30-3 included in the window layer 30 are formed of the same material, for example, formed of InAlAs. Crystal lattice strain is less likely to occur.

The contact layer 32 is formed of a material different from that of the window layer 30, and is formed of, for example, InGaAs. The contact layer 32 and the window layer 30 are in a heterojunction. The heterojunction interface is revealed on the side surfaces of the mesa 10. According to the first embodiment, the dark current can be reduced at the heterojunction interface. By alleviating the electric field concentration on the heterojunction interface, it is possible to effectively reduce the edge breakdown.

As shown in FIG. 1, the mesa 10 has a ring shape in a planar shape. The junction interface between the contact layer 32 and the window layer 30 is ring shape. The dark current can be reduced at the ring shape junction interface. By alleviating the electric field concentration on the junction interface, it is possible to reduce the edge breakdown. The mesa 10 may include the contact layer 32 and a part of the window layer 30. The window layer 30 is etched in a ring shape, and the contact layer 32 is stacked on the ring shape portion.

The buffer layer 20, the multiplication layer 22, the adjusting layer 24, the light-absorbing layer 26, and the window layer 30 form the mesa 13. The mesa 10 is located above the mesa 13 and protrudes from the mesa 13 in the Z-axis direction. As shown in FIG. 2B, the depletion region 40 is expanded in the mesa 13 by the application of the voltage. The element capacitance is reduced by the depletion of the window layer 30 and the like. The impurity concentration of the window layer 30 is higher as the position is closer to the contact layer 32. As shown in FIG. 2B, the depletion region 40 is expanded, for example, partway through the semiconductor layer 30-3 in the Z-axis direction, but does not reach the junction interface between the semiconductor layer 30-3 and the contact layer 32. The electric field applied to the junction interface can be reduced.

The light receiving device 100 is an avalanche photodiode, and a voltage of, for example, several tens of volts is applied thereto. Since the electric field concentration is alleviated, it is possible to reduce the edge breakdown. The first embodiment may be applied to photodiodes other than the avalanche photodiode.

### Second Embodiment

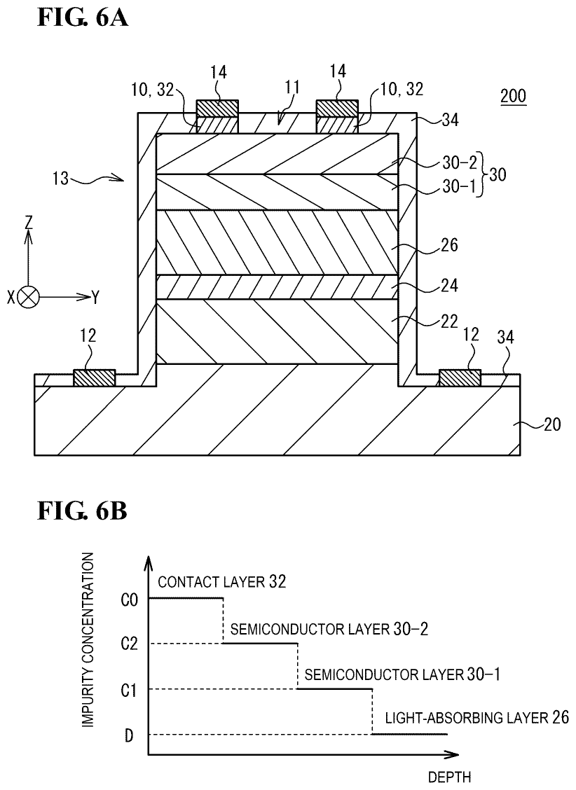

FIG. 6A is a cross-sectional view illustrating a light receiving device 200 according to a second embodiment. The description of the same configuration as that of the first embodiment will be omitted. As shown in FIG. 6A, a window layer 30 has two semiconductor layers, a semiconductor layer 30-1 and a semiconductor layer 30-2. The semiconductor layer 30-1 and the semiconductor layer 30-2 are stacked in this order between a light-absorbing layer 26 and a contact layer 32.

FIG. 6B is a schematic diagram illustrating impurity concentration. An impurity concentration C0 of the contact layer 32 is higher than an impurity concentration C2 of the semiconductor layer 30-2, for example, 10 times the C2. The impurity concentration C2 of the semiconductor layer 30-2 is higher than an impurity concentration C1 of the semiconductor layer 30-1, and is, for example, 10 times the C1.

According to the second embodiment, the window layer 30 has two semiconductor layers: the semiconductor layer 30-1 and the semiconductor layer 30-2. The semiconductor layer 30-1 is stacked on the light-absorbing layer 26. The semiconductor layer 30-2 is stacked on the semiconductor layer 30-1 and has a higher impurity concentration than the semiconductor layer 30-1. Since the concentration difference between the contact layer 32 and the light-absorbing layer 26 becomes small, the dark current can be reduced. The electric field concentration at the heterojunction interface between the semiconductor layer 30-2 and the contact layer 32 can be alleviated.

### Third Embodiment

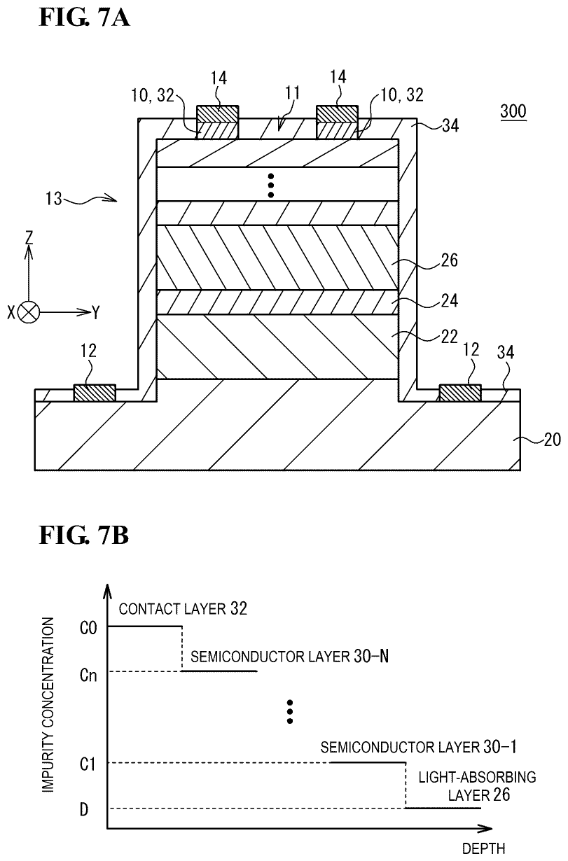

FIG. 7A is a cross-sectional view illustrating a light receiving device 300 according to a third embodiment. The description of the same configuration as that of the first embodiment or the second embodiment will be omitted. As shown in FIG. 7A, a window layer 30 has N semiconductor layers: a semiconductor layer 30-1 to a semiconductor layer 30-N. N is a natural number, and is, for example, four or more. The semiconductor layer 30-1 to the semiconductor layer 30-N are stacked in this order between a light-absorbing layer 26 and a contact layer 32.

FIG. 7B is a schematic view illustrating impurity concentration. Among the semiconductor layers included in the window layer 30, an impurity concentration Cn of the semiconductor layer 30-N is the highest. Among the semiconductor layers included in the window layer 30, the impurity concentration C1 of the semiconductor layer 30-1 is the lowest. The impurity concentration decreases stepwise from the semiconductor layer 30-N to the semiconductor layer 30-1. That is, the impurity concentration of the semiconductor layer close to the contact layer 32 is higher than the impurity concentration of the semiconductor layer close to the light-absorbing layer 26. The impurity concentration C0 of the contact layer 32 is higher than the impurity concentration Cn of the semiconductor layer 30-N.

According to the third embodiment, the window layer 30 has N semiconductor layers. Among the N semiconductor layers, a layer close to the light-absorbing layer 26 has a low impurity concentration. The layer closer to the contact layer 32 has a higher impurity concentration. The concentration difference between the contact layer 32 and the window layer 30 and between the plurality of semiconductor layers in the window layer 30 is reduced. Thus, the dark current can be reduced. The electric field concentration at the heterojunction interface between the semiconductor layer 30-N and the contact layer 32 can be alleviated.

The ratio of impurity concentration in the semiconductor layers adjacent to each other in the window layer 30 is, for example, about 10 times, and may be 2 times, 5 times, 7 times, 8 times, or the like. The N semiconductor layers of the window layer 30 may include the semiconductor layers having a similar impurity concentration. The impurity may be decreased from the semiconductor layer 30-N to the semiconductor layer 30-1.

### Fourth Embodiment

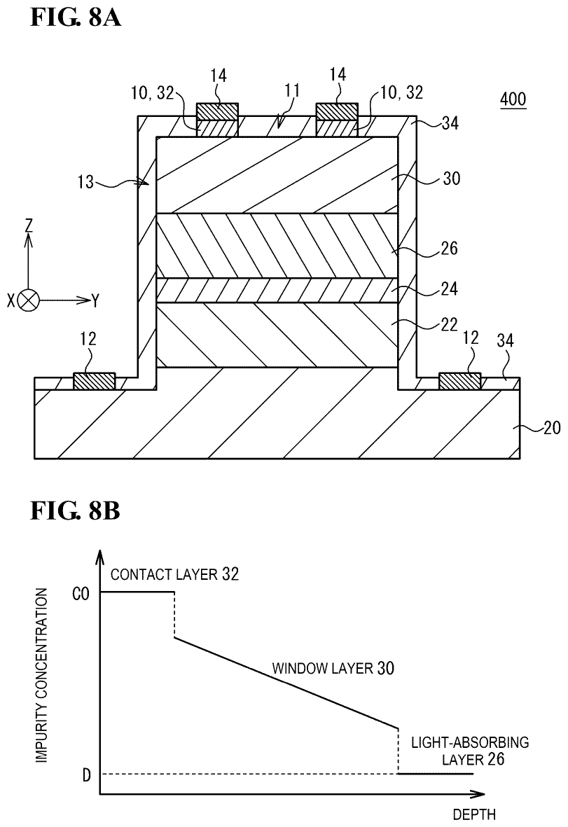

FIG. 8A is a cross-sectional view illustrating a light receiving device 400 according to a fourth embodiment. The description of the same configuration as that of any one of the first embodiment to the third embodiment will be omitted. As shown in FIG. 8A, a light-absorbing layer 26, a window layer 30, and a contact layer 32 are stacked in this order. The window layer 30 has the p-type conductivity type.

FIG. 8B is a schematic view illustrating impurity concentration. The window layer 30 is a single layer, but the impurity concentration in the window layer 30 is not constant. The impurity concentration is high in a portion close to the contact layer 32 and low in a portion close to the light-absorbing layer 26. For example, the impurity concentration of the window layer 30 continuously changes with respect to the position in a Z-axis direction. The impurity concentration of the window layer 30 has a maximum value at a bonding portion between the window layer 30 and the contact layer 32. The maximum value is, for example, 1×10¹⁸ cm⁻³. The impurity concentration of the window layer 30 has a minimum value at a bonding portion between the window layer 30 and the light-absorbing layer 26. The minimum is, for example, 1×10¹⁶ cm⁻³.

According to the fourth embodiment, a portion of the window layer 30 close to the light-absorbing layer 26 has a low impurity concentration. A portion close to the contact layer 32 has a high impurity concentration. Since the concentration difference between the layers is reduced between the contact layer 32 and the window layer 30, the dark current can be reduced. The electric field concentration at the heterojunction interface between the window layer 30 and the contact layer 32 can be alleviated.

The impurity concentration of the window layer 30 may vary linearly or non-linearly with respect to the position. The third embodiment and the fourth embodiment may be combined. The window layer 30 has the plurality of semiconductor layers: the semiconductor layer 30-1 to the semiconductor layer 30-N. The impurity concentration of any one of the N semiconductor layers may be continuously changed.

Although the embodiments of the present disclosure have been described in detail, the present disclosure is not limited to the specific embodiments, and various modifications and changes can be made within the scope of the gist of the present disclosure described in the claims.

What is claimed is:

1. A light receiving device comprising:
a first semiconductor layer, a light-absorbing layer, a second semiconductor layer, and a third semiconductor layer that are stacked in this order;
a first electrode electrically connected to the first semiconductor layer; and
a second electrode electrically connected to the third semiconductor layer,
wherein the third semiconductor layer is configured to form a first mesa protruding from the second semiconductor layer,
wherein the first semiconductor layer has a first conductivity type,
wherein the second semiconductor layer and the third semiconductor layer have a second conductivity type,
wherein an impurity concentration in the third semiconductor layer is higher than an impurity concentration in the second semiconductor layer, and
wherein an impurity concentration in the second semiconductor layer decreases from the third semiconductor layer toward the light-absorbing layer.

2. The light receiving device according to claim 1,
wherein the second semiconductor layer includes a plurality of semiconductor layers stacked between the light-absorbing layer and the third semiconductor layer, and
wherein an impurity concentration in a semiconductor layer of the plurality of semiconductor layers close to the third semiconductor layer is higher than an impurity concentration in a semiconductor layer of the plurality of semiconductor layers close to the light-absorbing layer.

3. The light receiving device according to claim 1,
wherein the second semiconductor layer includes a fourth semiconductor layer, a fifth semiconductor layer, and a sixth semiconductor layer,
wherein the light-absorbing layer, the fourth semiconductor layer, the fifth semiconductor layer, the sixth semiconductor layer, and the third semiconductor layer are stacked in this order,
wherein an impurity concentration in the fifth semiconductor layer is higher than an impurity concentration in the fourth semiconductor layer, and
wherein an impurity concentration in the sixth semiconductor layer is higher than an impurity concentration in the fifth semiconductor layer.

4. The light receiving device according to claim 2,
wherein the plurality of semiconductor layers included in the second semiconductor layer are formed of a same material.

5. The light receiving device according to claim 1,
wherein the second semiconductor layer is formed of a material different from a material of the third semiconductor layer.

6. The light receiving device according to claim 1,
wherein the first mesa formed by the second semiconductor layer has a ring shape in a planar shape.

7. The light receiving device according to claim 1,
wherein the light-absorbing layer and the second semiconductor layer are configured to form a second mesa.

8. The light receiving device according to claim 1,
wherein the first semiconductor layer has an n-type conductivity type, and
wherein the second semiconductor layer and the third semiconductor layer have a p-type conductivity type.

9. The light receiving device of claim 1,
wherein the light receiving device is an avalanche photodiode, and
wherein the light receiving device includes a multiplication layer stacked between the first semiconductor layer and the third semiconductor layer.
